(19) United States
(12) Patent Application Publication
(10) Pub. No.: US 2022/0336255 A1
(43) Pub. Date: Oct. 20, 2022

(54) Mass Transfer Device and Method

(71) Applicant: CHONGQING KONKA PHOTOELECTRIC TECHNOLOGY RESEARCH INSTITUTE CO., LTD., Chongqing (CN)

(72) Inventor: Shiyuan XU, Chongqing (CN)

(21) Appl. No.: 17/263,883

(22) PCT Filed: Dec. 30, 2019
(86) PCT No.: PCT/CN2019/130029

§ 371 Date: Jan. 27, 2021

(51) Int. Cl. H01L 21/683

(52) U.S. Cl. CPC H01L 21/6838

(57) ABSTRACT

Provided is a mass transfer device and method. The mass transfer device includes: a housing, and a sliding plate installed in the housing, a back surface of the housing is provided with adsorption holes for adsorbing micro-elements, a front surface of the housing is provided with vacuum holes, the sliding plate is provided with first through holes, and the sliding plate can be slid in the housing and connect or disconnect the adsorption holes and the vacuum holes through the first through holes. Through controlling the sliding plate to be slid for a first distance and connect the corresponding vacuum hole and adsorption hole, a mass transfer can be performed; and through controlling the sliding plate to be slid for a second distance and connect the corresponding vacuum hole and adsorption hole, the mass transfer can also be performed.

### TECHNICAL FIELD

The present disclosure relates to the technical field of mass transfer, and in particular to a mass transfer device and method.

### BACKGROUND

A mass transfer device is applied to the transfer of a large number of micro-elements (such as a Micro-LED). Because the micro-elements such as the Micro-LED are divided into R, G and B three-color Micro-LEDs, the mass transfer device in the related art generally adopts an all-take and all-transfer mode, and a certain part of the micro-elements may not be selectively transferred.

Therefore, a related art needs to be improved and developed.

### SUMMARY

A technical problem to be solved by the disclosure is to provide a mass transfer device and method in view of the above disadvantages of the related art, and aim to solve the problem that a certain part of micro-elements may not be selectively transferred in the related art.

A technical scheme provided by the embodiment of the present disclosure for solving the technical problem is as follows.

A mass transfer device is provided by an embodiments of the present disclosure, and the mass transfer device includes: a housing, and a sliding plate installed in the housing, herein a back surface of the housing is provided with adsorption holes for adsorbing micro-elements, a front surface of the housing is provided with vacuum holes, the sliding plate is provided with first through holes, and the sliding plate may be slid in the housing and connect or disconnect the adsorption holes and the vacuum holes through the first through holes.

In an embodiment, in the mass transfer device, the adsorption holes are distributed in a first point array.

In an embodiment, in the mass transfer device, the vacuum holes are distributed in a second point array or a first line array, herein lines in the first line array are arranged corresponding to connecting lines of the adsorption holes.

In an embodiment, in the mass transfer device, the first through holes are distributed in a third point array or a second line array, herein lines in the second line array are arranged corresponding to the connecting lines of the adsorption holes.

In an embodiment, in the mass transfer device, the number of points in the third point array is less than the number of points in the second point array, and the number of the lines in the second line array is less than the number of the lines in the first line array.

In an embodiment, in the mass transfer device, the sliding plate is provided with second through holes, and the second through hole is located at ¼ of the two neighboring first through holes.

In an embodiment, in the mass transfer device, the sliding plate is provided with third through holes, and the third through hole is located at ½ of the two neighboring first through holes.

In an embodiment, the mass transfer device, herein the sliding plate is provided with fourth through holes, and the fourth through hole is located at ¾ of the two neighboring first through holes.

A mass transfer method is also provided by an embodiment of the present disclosure, and the method is applied to the mass transfer device as described above, and the method includes the following steps: the sliding plate is controlled to be slid for a first distance to connect the corresponding vacuum hole and adsorption hole, and mass transfer is performed; the sliding plate is controlled to be slid for a second distance to connect the corresponding vacuum hole and adsorption hole, and the mass transfer is performed, herein the vacuum hole and the adsorption hole connected while the sliding plate is slid for the second distance are different from the vacuum hole and the adsorption hole connected while the sliding plate is slid for the first distance.

In an embodiment, the step of controlling the sliding plate to be slid for a first distance to connect the corresponding vacuum hole and adsorption hole includes: the sliding plate is controlled to be slid for the first distance so that the first through holes or the second through holes or the third through holes or the fourth through holes are connected with the vacuum holes and the adsorption holes.

The beneficial effects achieved by the embodiments are as follows: through controlling the sliding plate to be slid for the first distance to connect the corresponding vacuum hole and adsorption hole, the mass transfer can be performed; and through controlling the sliding plate to be slid for the second distance to connect the corresponding vacuum hole and adsorption hole, the mass transfer can also be performed, herein the vacuum hole and the adsorption hole connected while the sliding plate is slid for the second distance are different from the vacuum hole and the adsorption hole connected while the sliding plate is slid for the first distance. In other words, the vacuum holes and the adsorption holes can be selectively connected by controlling a sliding distance of the sliding plate.

### BRIEF DESCRIPTION OF THE DRAWINGS

FIG. 1 is a first structure schematic diagram of a mass transfer device in an embodiment of the present disclosure.

FIG. 2 is a second structure schematic diagram of the mass transfer device in an embodiment of the present disclosure.

FIG. 3 is a first structure schematic diagram of a sliding plate in an embodiment of the present disclosure.

FIG. 4 is a first sectional view of the mass transfer device in an embodiment of the present disclosure.

FIG. 5 is a second sectional view of the mass transfer device in an embodiment of the present disclosure.

FIG. 6 is a schematic diagram of transfer of the mass transfer device in an embodiment of the present disclosure.

FIG. 7 is a second structure schematic diagram of the sliding plate in an embodiment of the present disclosure.

FIG. 8 is a third sectional view of the mass transfer device in an embodiment of the present disclosure.

FIG. 9 is a fourth sectional view of the mass transfer device in an embodiment of the present disclosure.

FIG. 10 is a fifth sectional view of the mass transfer device in an embodiment of the present disclosure.

FIG. 11 is a sixth sectional view of the mass transfer device in an embodiment of the present disclosure.

### DETAILED DESCRIPTION OF THE EMBODIMENTS

In order to make purposes, technical schemes and advantages of the disclosure more clear and definite, the disclosure is further described in detail below with reference to drawings and embodiments. It should be understood that the specific embodiments described here are only used to explain the disclosure, rather than to limit the disclosure.

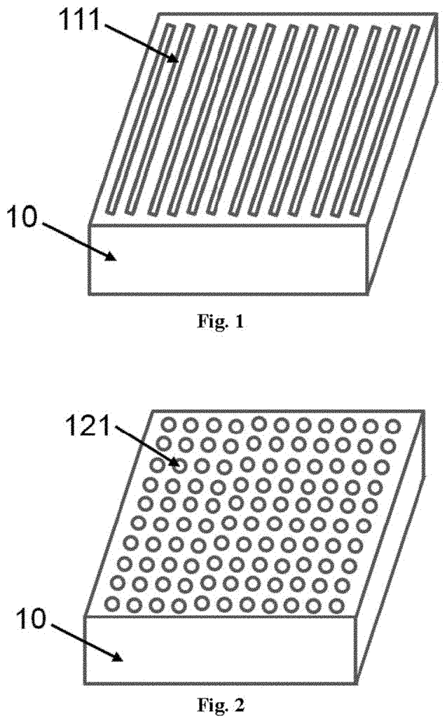

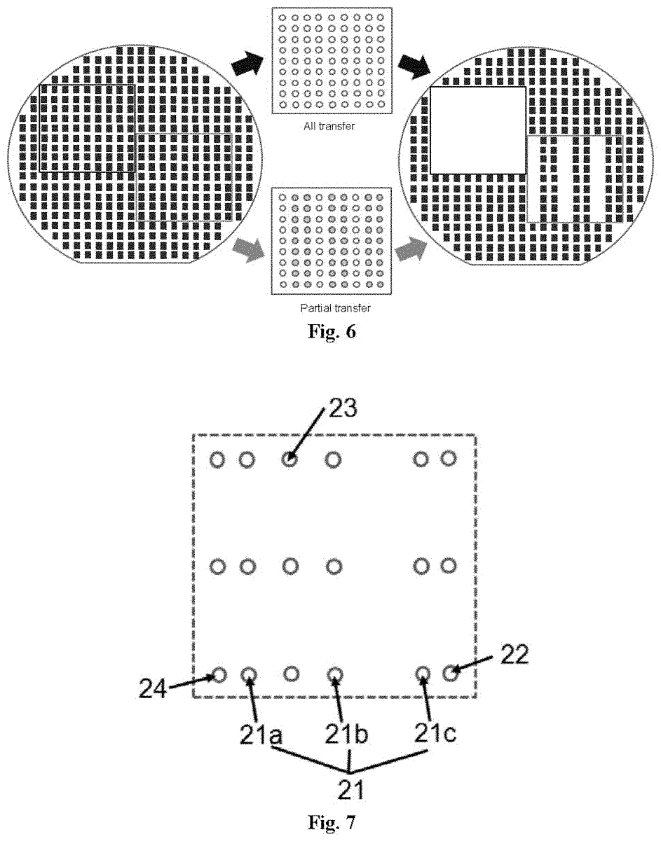

Referring to FIG. 1 to FIG. 11, the present disclosure provides some embodiments of a mass transfer device.

As shown in FIG. 4, a mass transfer device provided by an embodiment of the present disclosure includes a housing 10, and a sliding plate 20 installed in the housing 10. A back surface of the housing 10 is provided with adsorption holes 121 for adsorbing micro-elements 30, a front surface of the housing 10 is provided with vacuum holes 111, the sliding plate 20 is provided with first through holes 21, and the sliding plate 20 may be slid in the housing 10 and connect or disconnect the adsorption holes 121 and the vacuum holes 111 through the first through holes 21.

Specifically, as shown in FIG. 4, the housing 10 includes: a face plate 11 and a bottom plate 12 connected mutually; the vacuum holes 111 are located in the face plate 11 and pass through the face plate 11, the adsorption holes 121 are located in the bottom plate 12 and pass through the bottom plate 12. There is a gap between the face plate 11 and the bottom plate 12, the sliding plate 20 is located in the gap, and a height of the gap is matched with a thickness of the sliding plate 20, so that the sliding plate 20 may be slid in the gap without air leakage.

It is to be noted that, through controlling the sliding plate 20 to be slid for a first distance and connect the corresponding vacuum hole 111 and adsorption hole 121, mass transfer may be performed; and through controlling the sliding plate 20 to be slid for a second distance and connect the corresponding vacuum hole 111 and adsorption hole 121, the mass transfer may also be performed, herein the vacuum hole 111 and the adsorption hole 121 connected while the sliding plate 20 is slid for the second distance are different from the vacuum hole 111 and the adsorption hole 121 connected while the sliding plate 20 is slid for the first distance. In other words, the vacuum holes 111 and the adsorption holes 121 may be selectively connected by controlling a sliding distance of the sliding plate 20.

In an embodiment of the disclosure, as shown in FIG. 2, the adsorption holes 121 are distributed in a first point array. Specifically, the micro-elements 30 are generally distributed by using a point array, therefore, the adsorption holes 121 are arranged to be distributed in the corresponding point array. Certainly, the point array here may be a row-column matrix, a circular matrix and the like, while the row-column matrix is used, the sliding plate 20 is slid along a direction of a row or a column; and while the circular matrix is used, the sliding plate 20 is rotated (slid) along a circumferential direction by using a circle center as a spin axis. In the present embodiment, the row-column matrix is used for description.

In an embodiment of the disclosure, the vacuum holes 111 are distributed in a second point array or a first line array (as shown in FIG. 1), herein lines in the first line array are arranged corresponding to connecting lines of the adsorption holes 121. Specifically, the vacuum holes 111 form the second point array, and the second point array is arranged corresponding to the first point array, in other words, all of the adsorption holes 121 must be covered by the vacuum holes 111, so that each adsorption hole 121 may adsorb the micro-elements 30. Points of the adsorption holes 121 may also be connected into lines, so a line array is formed, for example, each row or column of the point array is connected to form a row or a column, so that each row or column may share a vacuum channel and is connected with a vacuum machine, a vacuum degree of such a row or column is the same, and an adsorption force is also the same.

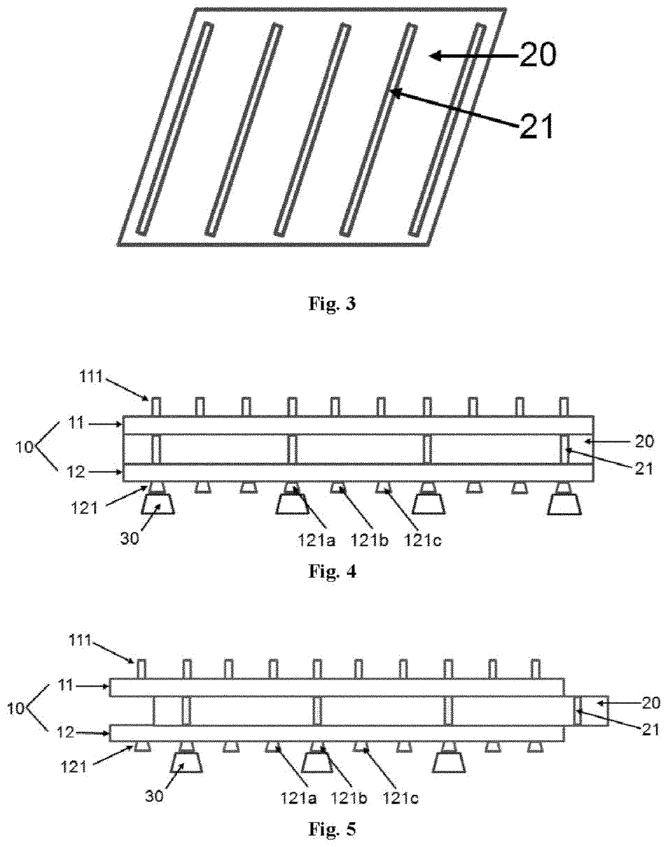

In an embodiment of the disclosure, the first through holes 21 are distributed in a third point array or a second line array (as shown in FIG. 3), herein lines in the second line array are arranged corresponding to the connecting lines of the adsorption holes 121.

Specifically, the first through holes 21 in the sliding plate 20 may cover all of the adsorption holes 121, or may only cover a part of the adsorption holes 121. If the first through holes 21 cover all of the adsorption holes 121, the first through holes 21 may be connected with all of the vacuum holes 111 and the adsorption holes 121 for one time, and all transfer is achieved. If the first through holes 21 cover a part of the adsorption holes 121, the first through holes 21 may be only connected with a part of the vacuum holes 111 and the adsorption holes 121 for one time, and partial transfer is achieved; and after the sliding plate 20 is controlled to be slid, the first through holes 21 may be connected with the other part of the vacuum holes 111 and the adsorption holes 121, and the corresponding partial transfer is achieved. For example, as shown in FIG. 4 and FIG. 5, three-color Micro-LEDs are uniformly distributed, each color is successively arranged, the first through holes 21 only correspond to one color for one time, may correspond to the second color after the sliding plate 20 is slid, and may correspond to the third color while the sliding plate is continuously slid, thereby selective transfer of the different colors is achieved.

In an embodiment of the disclosure, the number of points in the third point array is less than the number of points in the second point array, as shown in FIGS. 1-3, the number of the lines in the second line array is less than the number of the lines in the first line array. Specifically, the partial transfer may be achieved by using a smaller number of the points or the lines. Specifically, as shown in FIGS. 4-5, the adsorption hole 121 includes a first sub-adsorption hole 121a, a second sub-adsorption hole 121b, and a third sub-adsorption hole 121c which are successively arranged. The first sub-adsorption hole 121a, the second sub-adsorption hole 121b, and the third sub-adsorption hole 121c are repeatedly arranged as a repeating unit to form the overall adsorption hole 121. If a distance between two neighboring adsorption holes 121 is D, a distance between two neighboring sub-adsorption holes is 3D, namely it is 3 times of the distance between the two neighboring adsorption holes 121. As shown in FIG. 4-5, the first through holes 21 only cover the first sub-adsorption hole 121a, the second sub-adsorption hole 121b or the third sub-adsorption hole 121c, through controlling the sliding plate 20 to be moved for the D each time, the first sub-adsorption hole 121a, the second sub-adsorption hole 121b or the third sub-adsorption hole 121c connected with it may be changed, thereby 3 types of the micro-elements 30 may be selectively adsorbed.

In an embodiment of the disclosure, as shown in FIG. 7 and FIG. 11, the sliding plate 20 is provided with second through holes 22, and the second through hole 22 is located at ¼ of the two neighboring first through holes 21. The sliding plate 20 is provided with third through holes 23, and the third through hole 23 is located at ½ of the two neighboring first through holes 21. The sliding plate 20 is provided with fourth through holes 24, and the fourth through hole 24 is located at ¾ of the two neighboring first through holes 21.

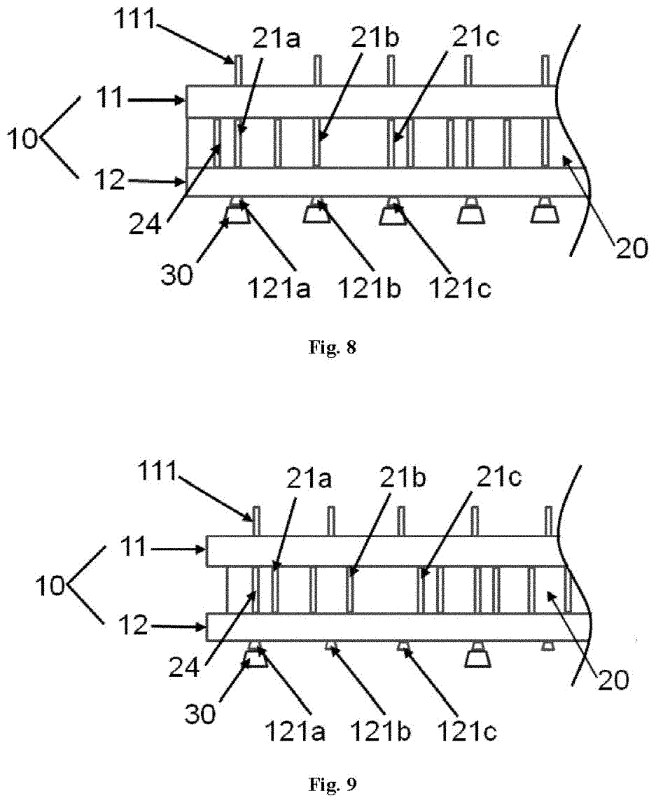

Specifically, based on the first through holes 21, the second through holes 22, the third through holes 23 or the fourth through holes 24 may be installed to further improve optionality of the mass transfer device. For example, the first through holes 21 adopt a mode of full-coverage of the adsorption holes 121, the first through holes 21 are used to connect the adsorption holes 121 and the vacuum holes 111, so the full transfer may be achieved (as shown in FIGS. 7 and 8). The second through holes 22, the third through holes 23 and the fourth through holes 24 all adopt a mode of partial-coverage. The distance between the two neighboring first through holes 21 is marked as D, the second through hole 22 is located at ¼D of the two neighboring first through holes 21, in other words, while the sliding plate 20 is moved for ¼D (or ¾D), the second through holes 22 may replace a part of the first through holes 21, and connect a part of the adsorption holes 121 and the vacuum holes 111, the partial transfer is achieved (as shown in FIG. 7 and FIGS. 9 to 11). Similarly, while the sliding plate 20 is moved for ½D, the third through holes 23 may replace a part of the first through holes 21, and connect a part of the adsorption holes 121 and the vacuum holes 111; and while the sliding plate 20 is moved for ¾D (or ¼D), the fourth through holes 24 may replace a part of the first through holes 21, and connect a part of the adsorption holes 121 and the vacuum holes 111.

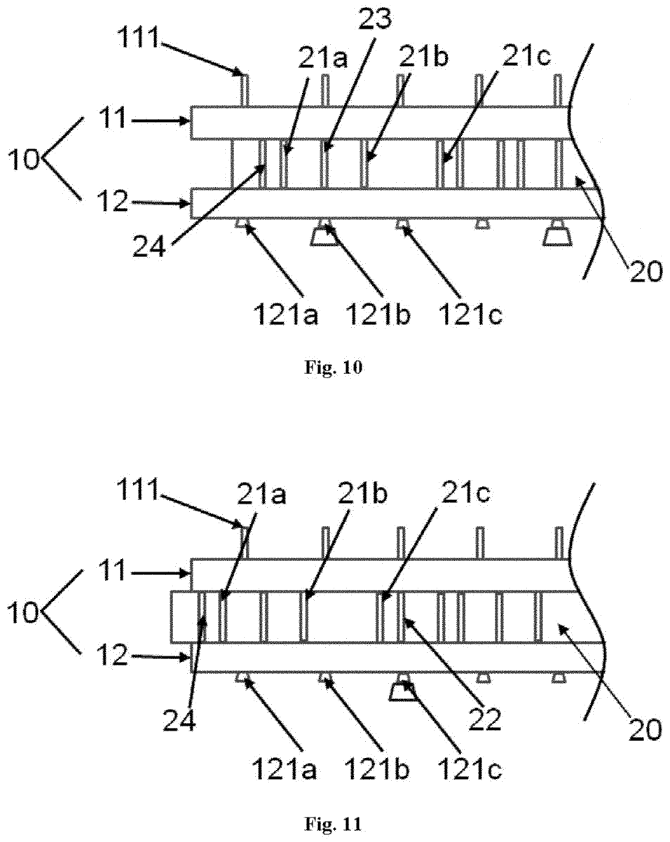

One or more of the first through holes 21, the second through holes 22, the third through holes 23 and the fourth through holes 24 may be optionally arranged in the sliding plate 20. For example, while the first through holes 21, the second through holes 22, the third through holes 23 and the fourth through holes 24 are all installed in the sliding plate 20, the first through holes 21 cover all of the adsorption holes 121, and the second through holes 22, the third through holes 23 and the fourth through holes 24 all cover ⅓ of the adsorption holes 121. In order to reduce a moving distance of the sliding plate 20 as much as possible, the second through holes 22, the third through holes 23 and the fourth through holes 24 are arranged close to the adsorption holes 121 covered by them, specifically, as shown in the figure, the first through hole 21 includes: a first sub-through hole 21a, a second sub-through hole 21b, and a third sub-through hole 21c which are successively arranged; and the first sub-through hole 21a, the second sub-through hole 21b, and the third sub-through hole 21c are repeatedly arranged as a repeating unit to form the overall first through hole 21. If a distance between two neighboring first through holes 21 is D, a distance between two neighboring sub-through holes (such as two neighboring first sub-through holes 21a) is 3D, namely it is 3 times of the distance between the two neighboring first through holes 21. The second through hole 22 is located at ¼ of the third sub-through hole 21c and the first sub-through hole 21a; the third through hole 23 is located at ½ of the first sub-through hole 21a and the second sub-through hole 21b, or located at ½ of the second sub-through hole 21b and the third sub-through hole 21c; and the fourth through hole 24 is located at ¾ of the third sub-through hole 21c and the first sub-through hole 21a. The second through hole 22 is slid for ¼D towards a direction of the third sub-through hole 21c, so only the third sub-adsorption hole 121c is connected (as shown in FIG. 8 and FIG. 11); the third through hole 23 is slid for ½D towards a direction of the second sub-through hole 21b, so only the second sub-adsorption hole 121b is connected (as shown in FIG. 8 and FIG. 10); and the fourth through hole 24 is slid for ¼D towards a direction of the first sub-through hole 21a, so only the first sub-adsorption hole 121a is connected (as shown in FIG. 8 and FIG. 9).

Based on the above mass transfer device, the disclosure further provides a preferred embodiment of a mass transfer method.

As shown in FIG. 1, the mass transfer method of the embodiment of the disclosure includes the following steps.

At S100, the sliding plate 20 is controlled to be slid for a first distance and connect the corresponding vacuum hole 111 and adsorption hole 121, and mass transfer is performed.

Specifically, the sliding plate 20 is controlled to be slid for the first distance so that the first through holes 21, the second through holes 22, the third through holes 23 or the fourth through holes 24 are connected with the vacuum holes 111 and the adsorption holes 121. All or partial transfer may be achieved while the vacuum holes 111 and the adsorption holes 121 are connected by using the different through holes.

At S200, the sliding plate 20 is controlled to be slid for a second distance and connect the corresponding vacuum hole 111 and adsorption hole 121, and the mass transfer is performed, herein the vacuum hole 111 and the adsorption hole 121 connected while the sliding plate 20 is slid for the second distance are different from the vacuum hole 111 and the adsorption hole 121 connected while the sliding plate 20 is slid for the first distance.

Specifically, while the sliding plate 20 is controlled to be slid for the different distances, the vacuum hole 111 and the adsorption hole 121 connected may be changed, thereby selectivity transfer is achieved.

In conclusion, the disclosure provides a mass transfer device and method. The mass transfer device includes: a housing, and a sliding plate installed in the housing, herein a back surface of the housing is provided with adsorption holes for adsorbing micro-elements, a front surface of the housing is provided with vacuum holes, the sliding plate is provided with first through holes, and the sliding plate may be slid in the housing and connect or disconnect the adsorption holes and the vacuum holes through the first through holes. Through controlling the sliding plate to be slid for the first distance and connect the corresponding vacuum hole and adsorption hole, the mass transfer may be performed; and through controlling the sliding plate to be slid for the second distance and connect the corresponding vacuum hole and adsorption hole, the mass transfer may also be performed, herein the vacuum hole and the adsorption hole connected while the sliding plate is slid for the second distance are different from the vacuum hole and the adsorption hole connected while the sliding plate is slid for the first distance. In other words, the vacuum holes and the adsorption holes may be selectively connected by controlling a sliding distance of the sliding plate.

It should be understood that the application of the disclosure is not limited to the above examples, improvements or changes may be made by those of ordinary skill in the art according to the above description, and all of these improvements and changes shall fall within a scope of protection of appended claims of the present disclosure.

1. A mass transfer device, comprising: a housing, and a sliding plate installed in the housing, wherein a back surface of the housing is provided with adsorption holes for adsorbing micro-elements, a front surface of the housing is provided with vacuum holes, the sliding plate is provided with first through holes, and the sliding plate can be slid in the housing to connect or disconnect the adsorption holes and the vacuum holes through the first through holes.

2. The mass transfer device as claimed in claim 1, wherein the adsorption holes are distributed in a first point array.

3. The mass transfer device as claimed in claim 2, wherein the vacuum holes are distributed in a second point array or a first line array, wherein lines in the first line array are arranged corresponding to connecting lines of the adsorption holes.

4. The mass transfer device as claimed in claim 3, wherein the first through holes are distributed in a third point array or a second line array, wherein lines in the second line array are arranged corresponding to the connecting lines of the adsorption holes.

5. The mass transfer device as claimed in claim 4, wherein the number of points in the third point array is less than the number of points in the second point array, and the number of the lines in the second line array is less than the number of the lines in the first line array.

6. The mass transfer device as claimed in claim 3, wherein the sliding plate is provided with second through holes, and the second through hole is located at ¼ of the two neighboring first through holes.

7. The mass transfer device as claimed in claim 3, wherein the sliding plate is provided with third through holes, and the third through hole is located at ½ of the two neighboring first through holes.

8. The mass transfer device as claimed in claim 3, wherein the sliding plate is provided with fourth through holes, and the fourth through hole is located at ¾ of the two neighboring first through holes.

9. A mass transfer method, applied to the mass transfer device as claimed in claim 1, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

10. The mass transfer method as claimed in claim 9, wherein controlling the sliding plate to be slid for a first distance to connect the corresponding vacuum hole and adsorption hole comprises:
controlling the sliding plate to be slid for the first distance so that the first through holes or the second through holes or the third through holes or the fourth through holes are connected with the vacuum holes and the adsorption holes.

11. A mass transfer method, applied to the mass transfer device as claimed in claim 2, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

12. A mass transfer method, applied to the mass transfer device as claimed in claim 3, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

13. A mass transfer method, applied to the mass transfer device as claimed in claim 4, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

14. A mass transfer method, applied to the mass transfer device as claimed in claim 5, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

15. A mass transfer method, applied to the mass transfer device as claimed in claim 6, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

16. A mass transfer method, applied to the mass transfer device as claimed in claim 7, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.

17. A mass transfer method, applied to the mass transfer device as claimed in claim 8, and the method comprises the following steps:
controlling the sliding plate to be slid for a first distance to connect the corresponding vacuum hole and adsorption hole, and performing mass transfer; and
controlling the sliding plate to be slid for a second distance to connect the corresponding vacuum hole and adsorption hole, and performing the mass transfer, wherein the vacuum hole and the adsorption hole connected while the sliding plate is slid for the second distance are different from the vacuum hole and the adsorption hole connected while the sliding plate is slid for the first distance.
